(19) United States
(12) Patent Application Publication
(10) Pub. No.: US 2005/0088834 A1
(43) Pub. Date: Apr. 28, 2005

(54) Desk mounted power and accessory outlet apparatus

(76) Inventor: Henry Milan, Rochester Hills, MI (US)

Correspondence Address: MACMILLAN SOBANSKI & TODD, LLC;ONE MARITIME PLAZA FOURTH FLOOR, 720 WATER STREET, TOLEDO, OH, 43604-1619, US

(21) Appl. No.: 10/938,218

(22) Filed: Sep. 9, 2004

Related U.S. Application Data
(60) Provisional application No. 60/501,468, filed on Sep. 9, 2003.

(51) Int. Cl. G06F 1/26; G06F 1/32; H05K 7/02; H05K 7/04

(52) U.S. Cl. 361/810

(57) ABSTRACT

A combination power supply and work station apparatus includes a work station having a surface with an aperture formed therein and a power supply mounted on the work station in the aperture. The apparatus includes circuitry with an outlet for providing DC power to a peripheral device. The apparatus also includes a movable cover for selectively covering the outlet and at least one AC electrical outlet in the power supply exposed in the aperture. The apparatus further includes a device connected to the power supply and mounted on the work station in the aperture, the device having at least one port exposed in the aperture.

### BACKGROUND OF THE INVENTION

The present invention relates to a computer desk having a power core base hub including an integrated power source and computer accessories port for connection to peripheral devices located on or within the computer desk.

More particularly, the present invention relates to a computer desk having a power core base hub including an integrated power source for providing power to peripheral devices located on or within the computer desk, and for providing a stepped down power source to a USB hub board located within the power core base hub, and a plurality of USB communication ports on the USB hub board for interconnecting peripheral devices located on or within the computer desk to a computer.

Currently, computer technology has become more advanced with an ever increasing number of computer related peripheral devices to assist a computer user. Since peripheral devices interface with the operating system of the computer, it is advantageous for the computer and the peripheral devices to be in close proximity to one another for accessibility purposes for the computer user. A universal serial bus (USB) is a universal communication standard for connecting and communicating various peripheral devices to a computer. The USB allows the transfer of data between the computer and the peripheral devices. The USB further allows peripheral devices to be added without requiring add-in cards, dip switch settings, IRQ's and the like. Peripheral devices using the USB may be plugged in and implemented immediately. The USB detects the peripheral devices set up on the system and configures the software to operate the peripheral device automatically without having to restart your computer. The USB connects multiple peripheral devices to the computer through the use of USB ports on the back of the computer (usually two per PC) or a USB hub may be added to the system to connect (i.e. daisychain) multiple peripheral devices together. Examples of devices that are used with the USB connection include a keyboard, a mouse, a scanner, a joystick and a digital camera. The USB is also capable of sensing the power that is required to operate the peripheral device and can supply the required power to the peripheral device.

Typically, independent power strips are used to provide power to the multiple devices disposed throughout a user's workspace area such as a computer desk. Independent power bar strips are typically plugged into an outlet wall and are placed on the floor in an inconspicuous area such as between the computer desk and a wall and are usually burdensome to access. Communication lines between the computer and the peripheral devices are usually routed through one or more portal holes in the computer desk. These portal holes assist in routing the power and communication lines in an attempt to create an aesthetically pleasing workstation. However, even with the use of the independent power strip and the portal holes in the computer desk, the visual aesthetic of the wire routing is still displeasing as the power lines and communication lines become tangled, twisted, bunched and burdensome to service.

### SUMMARY OF THE INVENTION

The present invention concerns a combination power supply and work station apparatus including a work station having a surface with an aperture formed therein and a power supply mounted on the work station in the aperture and including circuitry with an outlet for providing DC power to a peripheral device. The apparatus also includes a movable cover for selectively covering the outlet and at least one AC electrical outlet in the power supply exposed in the aperture. The apparatus further includes a device connected to the power supply and mounted on the work station in the aperture, the device having at least one port exposed in the aperture.

### DESCRIPTION OF THE DRAWINGS

The above, as well as other advantages of the present invention, will become readily apparent to those skilled in the art from the following detailed description of a preferred embodiment when considered in the light of the accompanying drawings in which:

FIG. 1 is a perspective view of a computer work station according to the present invention;

FIG. 2 is a perspective view of the electrical circuits of a power supply and USB hub according to the present invention;

FIG. 3a is a perspective view of a computer work station protective cover and panel according to a first embodiment of the present invention;

FIG. 3b is a perspective view of a computer work station protective cover and panel according to a second embodiment of the present invention; and

FIG. 3c is a perspective view of the computer work station protective cover and panel according to a third embodiment of the present invention.

### DESCRIPTION OF THE PREFERRED EMBODIMENT

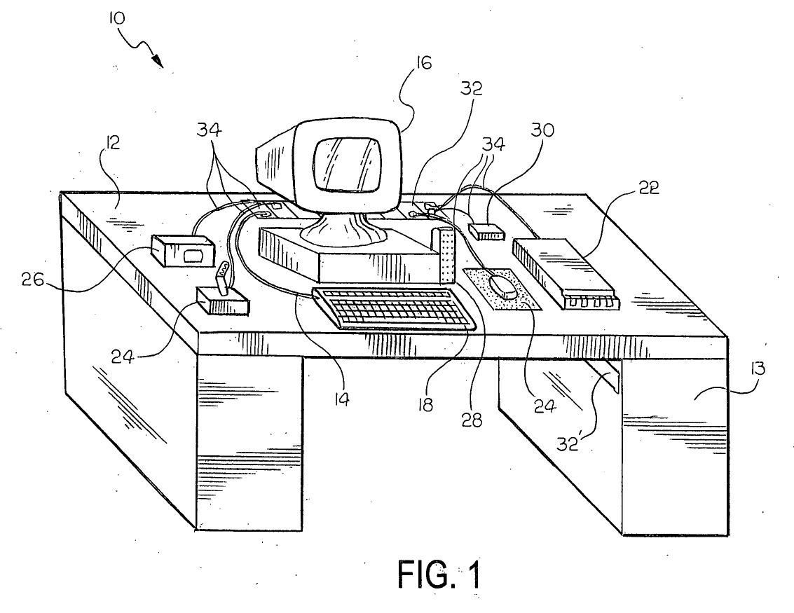

Referring now to FIG. 1, there is shown a computer work station 10 for hosting a computer system and accessories. The computer work station 10 includes a work desk 12 for supporting a plurality of computer related devices such as a main CPU unit 14, a video screen 16, and keyboard 18 and a mouse 20. A plurality of computer related peripheral devices such as a scanner 22, a joystick 24, a digital camera 26, speakers 28, and an external disk drive 30 are shown as common accessories utilized with the computer system.

The keyboard 18, the mouse 20 and the peripheral devices are communicably connected to a power core base hub 32 via a plurality of USB cables 34. Each peripheral device includes a USB port for connecting to the power core base hub 32 via one of the cables 34. The power core base hub 32 is communicably connected to the main CPU unit 14 via at least one main USB cable. The power core base hub 32 is integrated within the work desk 12 and is preferably accessible through a top surface centrally located in back of the CPU unit 14 so that peripheral devices located on each side of the CPU unit 14 are easily attachable to the power core base hub 32.

Alternatively, other locations may be utilized to integrate the power core base hub 32 within the work desk 12 to assist in making the computer work station 10 an efficient work area without the disorder of communication lines and power cables. The power core base hub 32 may be mounted or fastened to a bottom surface of the work desk with an access aperture formed through the work top to allow mechanical and electrical attachment between the plurality of USB cables 34 and the power core base hub 32. Alternatively, an interior compartment may be integrated into the work desk 12, such as an inwardly facing surface of a pedestal 13, to affix and enclose a power core base hub 32′.

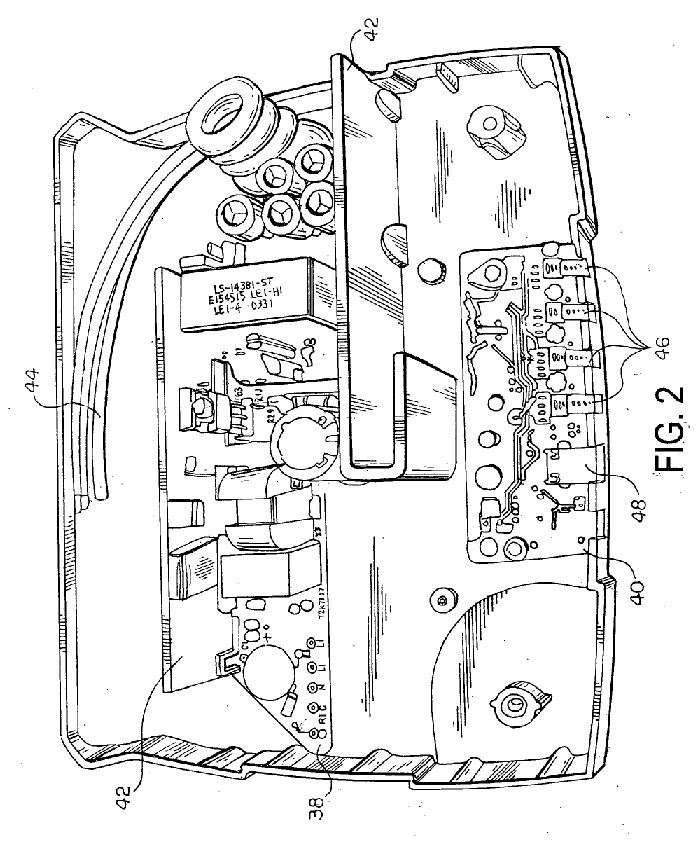

FIG. 2 shows the internal circuitry of the power core base hub 32. The power core base hub 32 includes a power board 38 and a USB hub board 40 encased within a single enclosure housing 36. The housing 36 is preferably made of plastic, but can be made of any type of material suitable to house the electrical components. A heat shield 42 separates the power board 38 from the USB hub board 40 so as to minimize the effects of the heat generated by the electrical power components of the power board 38. A power-in cord 44 is electrically attached to the power board 38 for receiving a power source (i.e. high voltage, alternating current 120V) from a main power supply such as an electrical wall outlet. The power board 38 may include a transformer for stepping down the power from a high voltage source to a low voltage source and an AC to DC converter for converting the stepped down power source from an alternating current power source to a direct current power source. The main power board may also include one or more circuits prior to the AC to DC converter and transformer for providing the 120V AC source to any computer accessory devices requiring the 120V AC source (i.e. CPU unit, video screen, printer, fax, or copier). A surge protector may also be incorporated in the power board 38 to shut down the power provided to any devices electrically attached to the power core base hub 32 in the event of a power surge or an overload on the main circuit of the main power supply.

The USB hub board 40 includes a plurality of peripheral USB hub ports 46 for electrically and mechanically releasably attaching to the plurality of USB cables 34 and at least one main USB hub port 48 for electrically and mechanically releasably attaching to the main USB cable. The plurality of peripheral USB hub ports 46 and the at least one main USB hub port 48 are aligned adjacent to one another and positioned in an upright position perpendicular to the planar surface of the work desk 12 so as to make the ports accessible to attach each respective USB cable as shown in FIG. 1. In addition to data transferred by the plurality of USB cables, electrical power may also be distributed to many of the USB peripheral devices utilizing the plurality of USB cables. The USB hub board 40 allows the PC to determine when power is needed to operate a respective peripheral device and to supply the necessary DC power source to operate the respective peripheral USB device.

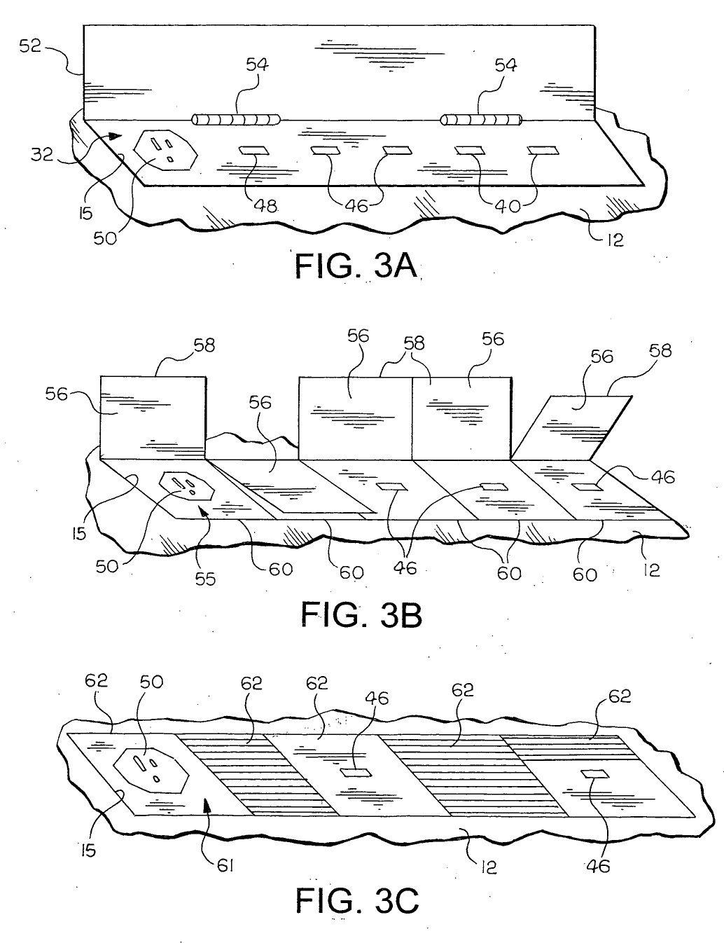

FIG. 3a is a perspective view of the power core base hub 32 positioned within the work desk 12 and exposed at the work surface. The work desk 12 includes an aperture 15 for allowing access to the peripheral USB hub ports 46 and the USB hub port 48. In addition, at least one 120V AC electrical outlet 50 is positioned within the aperture 15 for use by devices requiring high voltage, alternating current power. In the preferred embodiment, a protective cover 52 is pivotably attached to the power core base hub 32 by one or more hinges 54. The protective cover 52 is a protective shield to safeguard from any damage to each of the USB ports and the outlet when an object or device is placed over or on top of the base hub 32 when not in use. The protective cover 52 also acts as a dust shield to deter contaminants from entering the each of the USB ports and the outlet when unused.

FIG. 3b illustrates a second preferred embodiment according to the present invention wherein a power core base hub 55, similar to the base hub 32, has a plurality of individual protective covers 56 that are utilized for each respective USB port 46 and 48 and each respective 120V AC electrical outlet 50. Each respective protective cover 56 includes a plastic pinless “living” hinge for individually opening and closing a respective protective cover for a respective USB port or electrical outlet when in use. A respective protective cover 56 is horizontal when in the closed position and pivots vertically to the open position. As a result, contaminants may be prevented from entering those USB ports and electrical outlets when not in use. An interference condition may be formed between a respective forward edge 56 of each cover 58 and a respective edge portion 60 of the aperture 15 so as to maintain a closed position for each protective cover.

FIG. 3c illustrates a third preferred embodiment power core base hub 61 according to the present invention wherein a plurality of individual accordion protective covers 62 are positioned over each respective USB port and each respective 120V AC electrical outlet 50. The plurality of individual accordion protective covers 62 are individually slidable across the aperture 15, front to rear, and are received for storage at a rear portion of the base hub 61. As an individual accordion cover 62 slides into an open position, the individual accordion cover recesses into the upper surface of the work desk 12 so as to allow access to the respective USB port or 120V AC electrical outlet. Each individual accordion protective cover 62 prevents contaminants, debris, or any object from entering the port when not in use.

In the embodiment shown in the drawings, the built in power core base hubs 32, 55 and 61 are described as including a power board 38 and a USB hub board 40. However, the apparatus according to the present invention is not limited to such a combination. The apparatus can be simply a power supply providing one or more DC voltages at outlets for powering the computer related devices to be used. This power supply can be combined with one or more devices such as a docking station, a DSL router, an Ethernet switch, a USB hub (as described above), a wireless router and any other device that advantageously would be used at the computer work station 10.

In accordance with the provisions of the patent statutes, the present invention has been described in what is considered to represent its preferred embodiment. However, it should be noted that the invention can be practiced otherwise than as specifically illustrated and described without departing from its spirit or scope.

1. A combination power supply and work station comprising:
a work station having a surface with an aperture formed therein; and
a power supply mounted on said work station in said aperture and including circuitry with an outlet for providing DC power to a peripheral device.

2. The apparatus according to claim 1 including a movable cover for selectively covering said outlet.

3. The apparatus according to claim 1 including at least one AC electrical outlet in said power supply exposed in said aperture.

4. The apparatus according to claim 1 including a device connected to said power supply and mounted on said work station in said aperture.

5. The apparatus according to claim 4 wherein said device has at least one port exposed in said aperture.
